(19) United States
(12) Patent Application Publication
(10) Pub. No.: US 2023/0253194 A1
(43) Pub. Date: Aug. 10, 2023

(54) ATMOSPHERIC PLASMA PROCESSING METHOD AND ATMOSPHERIC PLASMA PROCESSING APPARATUS

(71) Applicant: FUJIFILM CORPORATION, Tokyo (JP)

(72) Inventor: Akihisa YOSHIDA, Kanagawa (JP)

(73) Assignee: FUJIFILM CORPORATION, Tokyo (JP)

(21) Appl. No.: 18/163,005

(22) Filed: Feb. 1, 2023

(30) Foreign Application Priority Data
Feb. 7, 2022 (JP) 2022-017023

(51) Int. Cl. H01J 37/32

(52) U.S. Cl. CPC H01J 37/32825; H01J 37/32449; H01J 37/32568; H01J 37/32733; H01J 2237/3321; H01J 2237/3326

(57) ABSTRACT

An object is to provide an atmospheric plasma processing method and an atmospheric plasma processing apparatus capable of suppressing a decrease in a processing speed caused by accompanying gas and performing highly efficient processing in a case where the processing is performed on a workpiece using atmospheric plasma by introducing plasma generation gas between a pair of electrodes and the workpiece from an inner side flow passage passing between the pair of electrodes while relatively moving the workpiece and the pair of electrodes. The object is achieved by defining p*, which is represented by Expression “p*=(h/2Uμ)×(−dP/dx)”, to satisfy 0<p*≤9 in a case where a distance between the pair of electrodes and the workpiece is denoted by h, a relative movement speed between the pair of electrodes and the workpiece is denoted by U, a viscosity of gas existing between the pair of electrodes and the workpiece is denoted by μ, a gas pressure between the pair of electrodes and the workpiece is denoted by P, and a position in a transport direction of the workpiece is denoted by x.

### CROSS-REFERENCE TO RELATED APPLICATIONS

The present application claims priority under 35 U.S.C. § 119 to Japanese Patent Application No. 2022-17023, filed on Feb. 7, 2022. The above application is hereby expressly incorporated by reference, in its entirety, into the present application.

### BACKGROUND OF THE INVENTION

### 1. Field of the Invention

The present invention relates to a plasma processing method using atmospheric plasma and an atmospheric plasma processing apparatus that performs the processing method.

### 2. Description of the Related Art

Atmospheric plasma processing is known in which plasma is generated under atmospheric pressure (near atmospheric pressure) to perform processing on any processing target (workpiece) such as a substrate.

For example, in atmospheric plasma film formation, as an example, plasma is generated by introducing plasma generation gas such as inert gas between electrodes, and raw material gas, which contains a film forming material introduced through a flow passage different from that between the electrodes, is activated using the plasma. In the atmospheric plasma film formation, the film formation is performed by attaching active species of the film forming material, which is obtained according to the above description, to the workpiece.

Since the atmospheric plasma processing is performed under atmospheric pressure, it does not require an expensive vacuum container such as a vacuum chamber, and thereby there is an advantage in that the apparatus cost can be reduced. Further, there is an advantage in that processing is possible even for a workpiece on which it is difficult to perform processing under vacuum.

On the other hand, as a method capable of efficiently performing processing such as film formation on a workpiece, a so-called roll-to-roll is known, in which a long workpiece wound in a roll shape is sent out in a longitudinal direction and the processing is performed while winding the workpiece. In the following description, the roll-to-roll is also referred to as “RtoR” for convenience.

From the viewpoint of productivity, it is conceivable to also use RtoR in the atmospheric plasma processing.

For example, in an RtoR type atmospheric plasma processing apparatus that performs plasma processing on a surface of a substrate (workpiece), JP2015-185494A discloses a plasma processing apparatus including an atmospheric plasma processing chamber for performing the atmospheric plasma processing, and an adjustment mechanism that has a front chamber and a rear chamber connected to a front and rear of the atmospheric plasma processing chamber through a substrate transport opening portion provided in the atmospheric plasma processing chamber and in which the volume fluctuates by means of partition plates installed in the front chamber and the rear chamber.

### SUMMARY OF THE INVENTION

As described above, the atmospheric plasma does not require an expensive vacuum container such as a vacuum chamber, and the processing is possible even for a workpiece on which it is difficult to perform processing under vacuum.

Furthermore, by using RtoR, more effective processing becomes possible in the atmospheric plasma processing having such an advantage. Moreover, since the atmospheric plasma does not need to transport the workpiece in the vacuum container, RtoR can be easily used.

However, as in RtoR, in a case where the atmospheric plasma processing is performed while the workpiece is being transported, it was found from the studies of the present inventors that as a transportation speed of the workpiece increases, a processing speed significantly decreases due to atmosphere gas (hereinafter referred to as accompanying gas) that is generated on a surface of the workpiece as the workpiece is transported, creating a manufacturing problem. In this case, the atmosphere gas includes not only the gas that exists in advance in the space but also the plasma generation gas, the raw material gas, and the like supplied from any flow passage.

The problem caused by such accompanying gas is the same in a case where the workpiece is fixed and an electrode is moved to perform the atmospheric plasma processing.

Since the accompanying gas is in an inactive state in many cases, it inactivates the generated plasma and the active species. Further, since the accompanying gas becomes an impurity in performing the desired processing, it inhibits the diffusion of the generated plasma and the active species, the reaction with the workpiece surface, and the like.

Therefore, in a case where the accompanying gas is generated, the number of active species including the plasma that reaches the surface of the workpiece is insufficient, which leads to a decrease in the processing effectiveness.

In a case where processing that uses the atmospheric plasma is performed while transporting a workpiece such as RtoR, the faster the transportation speed of the workpiece is, the more effectively the processing can be performed.

However, as the transportation speed of the workpiece increases, the amount of the accompanying gas increases, and the decrease in the processing speed due to the accompanying gas also increases.

An object of the embodiment of the present invention is to provide an atmospheric plasma processing method and an atmospheric plasma processing apparatus that performs the atmospheric plasma processing method, which are capable of suppressing the decrease in a processing speed caused by accompanying gas and performing highly efficient processing in a case where workpiece processing is performed such as film formation by atmospheric plasma while relatively moving a processing target (workpiece) such as a substrate and an electrode by using RtoR or the like.

In order to achieve the above-described object, an aspect of the present invention has the following configurations.

[1] An atmospheric plasma processing method, in which in a case where processing of a workpiece is performed using atmospheric plasma by introducing plasma generation gas between a pair of electrodes and the workpiece from an inner side flow passage, which passes between the pair of electrodes, while relatively moving the pair of electrodes and the workpiece, and a distance between the pair of electrodes and the workpiece is denoted by h, a relative movement speed between the workpiece and the pair of electrodes is denoted by U, a viscosity of gas existing between the pair of electrodes and the workpiece is denoted by u, a gas pressure between the pair of electrodes and the workpiece is denoted by P, and a position in a relative movement direction of the workpiece with respect to the pair of electrodes is denoted by x, p*, which is represented by Expression “p*=(h²/2Uμ)×(−dP/dx)”, satisfies 0<p*≤9.

[2] In the atmospheric plasma processing method according to [1], at least a portion between the pair of electrodes and the workpiece has a region in which gas flows in a direction opposite to the relative movement direction of the workpiece with respect to the pair of electrodes.

[3] In the atmospheric plasma processing method according to [1] or [2], plasma generation gas is further introduced from at least one of an upstream side flow passage positioned on an upstream side of the inner side flow passage in the relative movement direction of the workpiece with respect to the pair of electrodes or a downstream side flow passage positioned on a downstream side of the inner side flow passage in the relative movement direction of the workpiece with respect to the pair of electrodes.

[4] In the atmospheric plasma processing method according to [3], raw material gas used for performing film formation on the workpiece is introduced from at least one of the upstream side flow passage or the downstream side flow passage.

[5] In the atmospheric plasma processing method according to [3] or [4], the p* is set to satisfy 0<p*≤9 by making an introduction amount of gas from the downstream side flow passage larger than an introduction amount of gas from the upstream side flow passage.

[6] In the atmospheric plasma processing method according to any one of [3] to [5], the p* is set to satisfy 0<p*≤9 by making a gas discharge port of the upstream side flow passage and a gas discharge port of the downstream side flow passage different in area.

[7] In the atmospheric plasma processing method according to any one of [3] to [6], the p* is set to satisfy 0<p*≤9 by making shapes of surfaces of electrodes forming the pair of electrodes and facing the workpiece different between an upstream side flow passage side and a downstream side flow passage side.

[8] In the atmospheric plasma processing method according to any one of [1] to [7], the p* is set to satisfy 0<p*≤9 by providing an air supply unit on a downstream side of the inner side flow passage in the relative movement direction of the workpiece with respect to the pair of electrodes and supplying air from the air supply unit.

[9] In the atmospheric plasma processing method according to any one of [1] to [8], the p* is set to satisfy 0<p*≤9 by providing an exhaust unit on an upstream side of the inner side flow passage in the relative movement direction of the workpiece with respect to the pair of electrodes and exhausting air from the exhaust unit.

[10] An atmospheric plasma processing apparatus includes: a pair of electrodes; a movement unit that relatively moves a workpiece and the pair of electrodes along a path facing the pair of electrodes; an inner side flow passage that introduces gas between the pair of electrodes and the workpiece through between the pair of electrodes; and a gas flow control unit that controls a gas flow between the pair of electrodes and the workpiece such that in a case where a distance between the pair of electrodes and the workpiece is denoted by h, a relative movement speed between the pair of electrodes and the workpiece is denoted by U, a viscosity of gas existing between the pair of electrodes and the workpiece is denoted by μ, a gas pressure between the pair of electrodes and the workpiece is denoted by P, and a position in a relative movement direction of the workpiece with respect to the pair of electrodes is denoted by x, p*, which is represented by “p*=(h²/2Uμ)×(−dP/dx)”, satisfies 0<p*≤9.

[11] The atmospheric plasma processing apparatus according to [10] further includes: an upstream side flow passage for introducing gas between the pair of electrodes and the workpiece, on an upstream side of the inner side flow passage in the relative movement direction of the workpiece with respect to the pair of electrodes; and a downstream side flow passage for introducing gas between the pair of electrodes and the workpiece, on a downstream side of the inner side flow passage in the relative movement direction of the workpiece with respect to the pair of electrodes.

According to the embodiment of the present invention, it is possible to suppress a decrease in a processing speed caused by accompanying gas and to perform highly efficient processing in a case where the processing is performed on a workpiece using atmospheric plasma while relatively moving the workpiece and a pair of electrodes, by using RtoR or the like.

### BRIEF DESCRIPTION OF THE DRAWINGS

FIG. 1 is a diagram conceptually showing an example of an atmospheric plasma processing apparatus according to an embodiment of the present invention, which performs an example of an atmospheric plasma processing method of the embodiment of the present invention.

FIG. 2 is a graph showing an example of a relationship between a transportation speed of a workpiece and a film forming speed.

FIG. 3 is a conceptual diagram for describing a gas flow.

FIG. 4 is a graph showing an example of a gas flow between a pair of electrodes and the workpiece.

FIG. 5 is a graph showing a relationship between p* and the film forming speed in an example.

FIG. 6 is a conceptual diagram for describing atmospheric plasma film formation by using a remote diffusion mixing type.

### DESCRIPTION OF THE PREFERRED EMBODIMENTS

Hereinafter, an atmospheric plasma processing method and an atmospheric plasma processing apparatus according to the embodiment of the present invention will be described in detail with reference to suitable examples shown in the accompanying drawings.

The description of the configuration requirements described below is based on a representative embodiment of the present invention, but the embodiment of the present invention is not limited to such an embodiment.

In the present specification, a numerical range represented by using “-” means a range including numerical values before and after “-” as a lower limit value and an upper limit value.

Further, the drawings shown below are conceptual diagrams for describing the embodiment of the present invention. Therefore, the sizes, lengths, positional relationships, and the like of the configuration members do not always match those of actual objects.

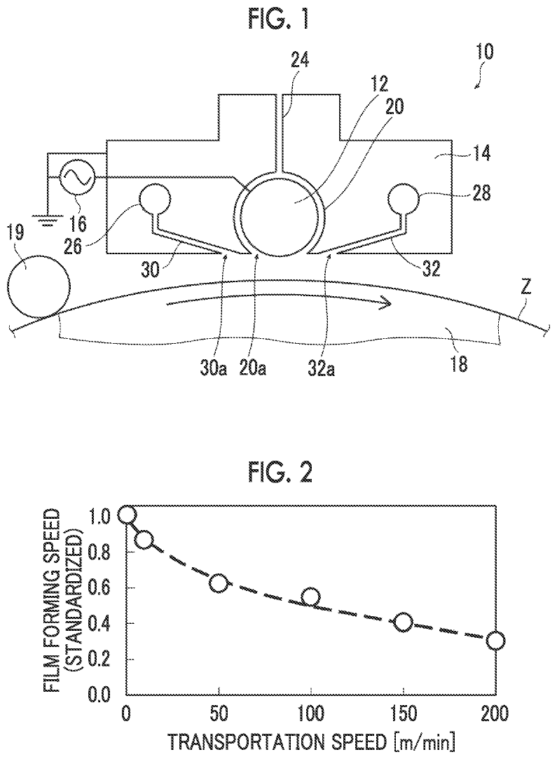

FIG. 1 conceptually shows an example of an atmospheric plasma film forming apparatus using the atmospheric plasma processing apparatus of the embodiment of the present invention, which performs film formation on a workpiece by using the atmospheric plasma processing method of the embodiment of the present invention.

The atmospheric plasma processing method according to the embodiment of the present invention is not limited to performing the film formation on the workpiece. That is, the atmospheric plasma processing method according to the embodiment of the present invention may be a method of performing processing on various workpieces using plasma, such as activation of a surface of the workpiece using plasma.

Further, the atmospheric plasma processing apparatus according to the embodiment of the present invention is not limited to the film forming apparatus and may be a processing apparatus that only performs processing on a workpiece using plasma. In this case, the processing apparatus may not have an upstream side flow passage and a downstream side flow passage described later. The atmospheric plasma processing according to the embodiment of the present invention may be performed by using the atmospheric plasma film forming apparatus shown in FIG. 1.

In the embodiment of the present invention, the workpiece is any processing target using the atmospheric plasma processing and is any target on which the various processing is possible using the atmospheric plasma while moving relative to an electrode.

Therefore, the workpiece may be not only a substrate having a sheet shape (a plate shape or a film shape) but also a substrate having any shape. Further, the substrate may be not only a long substrate corresponding to RtoR described below but also a substrate having a cut sheet shape (single-leaf type).

Furthermore, in the following description, the workpiece and a pair of electrodes are relatively moved by fixing the pair of electrodes and transporting the workpiece, but the embodiment of the present invention is not limited to this.

That is, in the plasma processing method and the plasma processing apparatus of the embodiment of the present invention, the workpiece and the pair of electrodes may be relatively moved by fixing the workpiece and moving the pair of electrodes, or the workpiece and the pair of electrodes may be relatively moved by moving both the workpiece and the pair of electrodes. In this case, the movement (transportation) of the pair of electrodes may be performed by a known method according to the size, configuration, and shape of the pair of electrodes.

An atmospheric plasma film forming apparatus 10 shown in FIG. 1 is an apparatus that performs atmospheric plasma film formation. The atmospheric plasma film formation is film formation by adhering any active species to a workpiece by using the atmospheric plasma processing, for example. Examples of the atmospheric plasma film forming method include a method of generating plasma by introducing plasma generation gas such as inert gas between the electrodes and activating raw material gas that contains a film forming material introduced through a flow passage different from that between electrodes using the plasma.

The atmospheric plasma film forming apparatus 10 shown in FIG. 1 is an apparatus that performs the film formation on a workpiece Z using remote diffusion mixing type atmospheric plasma (atmospheric pressure plasma chemical vapor deposition (CVD)) which performs the generation of the plasma and the contact of the plasma with the raw material gas at different locations, as an example. Further, the atmospheric plasma film forming apparatus 10 uses the above-described RtoR and performs the film formation on the workpiece Z using the atmospheric plasma while transporting the long workpiece Z in a longitudinal direction.

Therefore, the atmospheric plasma film forming apparatus 10 separately introduces the raw material gas and the plasma generation gas under atmospheric pressure (near atmospheric pressure) and mixes the plasma, which is generated between the pair of electrodes, and the raw material gas between the pair of electrodes and the workpiece Z to be transported. As a result, the raw material gas is activated using plasma, and the film formation is performed on the workpiece Z using the activated raw material gas (active species).

Specifically, as shown conceptually in FIG. 6 as an example of a general configuration, in the remote diffusion mixing type atmospheric plasma film forming apparatus, plasma is generated by introducing plasma generation gas PG into an inner side flow passage between a pair of electrodes 100, and the plasma is introduced between the pair of electrodes 100 and the workpiece Z. Further, raw material gas MG is introduced between the pair of electrodes and the workpiece Z from outer side flow passages 102a and 102b provided on an outer side of the inner side flow passage. As a result, the plasma that is generated between the pair of electrodes 100 is made in contact with and mixed with the raw material gas between the pair of electrodes and the workpiece Z, and the film formation is performed on the workpiece Z.

Here, in the embodiment of the present invention, the film formation is performed on the workpiece Z while the workpiece Z is transported, for example, in a direction of an arrow a. Therefore, in the apparatus shown in FIG. 6, the outer side flow passage 102a is an upstream side flow passage in the embodiment of the present invention, and the outer side flow passage 102b is a downstream side flow passage in the embodiment of the present invention.

In the following description, the atmospheric plasma film forming apparatus is also simply referred to as a film forming apparatus.

In the embodiment of the present invention, the material for forming the workpiece Z (the processing target), on which the film formation is performed, is not limited, and various known workpieces that allow film formation using atmospheric plasma and that preferably allow film formation using RtoR can be used.

For example, in the case where a workpiece Z (substrate to be processed) has a sheet shape as shown in the figure, examples include a resin film (a polymer film, a plastic film) made of a polymer material such as polyethylene terephthalate (PET), polyethylene polyvinyl chloride (PEN), polyethylene, polypropylene, polystyrene, polyamide, PVC, polycarbonate, polyacrylonitrile, polyimide, polyacrylate, and polymethacrylate, as well as silicon.

Further, the film that is used for the film formation on the workpiece Z is not limited, and various known materials that can be used for the film formation by the atmospheric plasma film formation can be used.

Examples include a gas barrier film such as silicon oxide, silicon oxynitride, silicon nitride, and aluminum oxide; a light reflection film or an antireflection film such as silicon oxide, titanium oxide, zinc oxide, tin oxide, and fluorine compounds; and a transparent conductive film such as indium tin oxide, tin oxide, indium oxide, zinc oxide, indium-cadmium oxide, cadmium-tin oxide, cadmium oxide, and gallium oxide, as well as a diamond-like carbon (DLC) film.

Further, various known raw material gases and plasma generation gases in accordance with the film, which is used for the film formation, can be used. The raw material gas is gas containing a component that becomes a film, which is used for the film formation, and the plasma generation gas is gas for generating plasma.

As an example, in a case where a DLC film is used for the film formation, hydrocarbon gas, such as methane gas, propane gas, and acetylene gas, is exemplified as the raw material gas, and argon gas is exemplified as the plasma generation gas, respectively. In a case where a silicon oxide film is used for the film formation, tetraethoxysilane (TEOS) gas is exemplified as the raw material gas, and nitrogen gas is exemplified as the plasma generation gas.

The film forming apparatus 10 shown in FIG. 1 includes a cylindrical electrode 12, a film forming unit 14, an AC power source 16, a drum 18, and a touch roll 19.

In FIG. 1, the cylindrical electrode 12, the film forming unit 14, the drum 18, and the touch roll 19 are shown in cross-sectional views, and in order to simplify the drawing and clearly show the configuration of the film forming apparatus 10, hatching is omitted.

Further, in the following description, for convenience, positions of each of the members are represented as top and bottom and horizontal (right and left) according to FIG. 1. However, a vertical direction (top-bottom direction) and a lateral direction (horizontal direction) do not necessarily match the actual usage state of the film forming apparatus 10.

The film forming apparatus 10 performs the film formation on a surface of the workpiece Z using the atmospheric plasma, in which the cylindrical electrode 12, the film forming unit 14, and the AC power source 16 are used while positioning the workpiece Z at a predetermined film forming position and transporting the workpiece Z in the longitudinal direction by winding the long workpiece Z around the drum 18 and transporting the workpiece Z.

In the following description, unless otherwise specified, “upstream” and “downstream” mean upstream and downstream in a transport direction of the workpiece Z.

As a preferred aspect, on an upstream side of the film forming unit 14, the touch roll 19 is provided for cutting off the accompanying gas on the workpiece Z by sandwiching the workpiece Z together with the drum 18.

The drum 18 is not limited, and in the processing of the workpiece Z such as the film formation using RtoR, various known drums (cans) that are used for transporting workpieces Z in the longitudinal direction while winding the workpieces Z around the drum 18 and positioning the workpiece Z at a predetermined position can be used.

In the embodiment of the present invention, a transport unit of the workpiece at the film forming position is not limited to the drum, and, for example, various known methods of transporting a sheet-shaped object, such as a method of using a nip roll as described in JP2015-185494A, a method of using a belt conveyor, and a method of using a moving stage, can be used.

However, the drum 18 as shown in the illustrated example is suitably used from the viewpoint that the workpiece can be stably held and transported at a predetermined position even in a case where high-speed transport is performed.

The touch roll 19 is not limited, and as long as the touch roll 19 can cut off the accompanying gas that moves with the workpiece Z by coming into contact with the workpiece Z to be transported and rotating with the workpiece Z, various known touch rolls that are used in known apparatuses for performing processing on a long workpiece (web) can be used.

Accordingly, the materials for forming the drum 18 and the touch roll 19 are not limited, and from the viewpoint of adhesiveness between the drum 18 and the touch roll 19, it is preferable that one surface is made of rubber, resin, or the like and the other surface is made of metal, or the like, so that the surfaces have different hardness. In a case where the surfaces of both the drum 18 and the touch roll 19 are made of rubber, resin, or the like, the entire body may be made of resin or the like, or the surface of the main body made of metal may be covered with rubber, resin, or the like.

Further, in the embodiment of the present invention, the method of transporting the workpiece Z is not limited, and as long as the workpiece Z can be transported at the desired transportation speed, various known methods of transporting a sheet-shaped object (a film-shaped or plate-shaped object) can be used.

In this respect, the same applies to a case where the workpiece is a substrate having any shape.

The cylindrical electrode 12 is a cylindrical-shaped electrode in which a direction orthogonal to a paper surface in FIG. 1 is a height direction (axis direction). The cylindrical electrode 12 is not limited, and various known cylindrical electrodes used for the atmospheric plasma film formation by so-called dielectric barrier discharge can be used.

Examples of the cylindrical electrode 12 include an electrode in which the surface of a cylinder made of a conductive material such as metal is covered with a dielectric such as quartz glass.

The film forming unit 14 is a block-shaped member made of metal.

The film forming unit 14 is provided with a flow passage formation portion 20 at a lower center portion in the lateral direction. The flow passage formation portion 20 is a cylindrical-shaped space having an inner diameter larger than an outer diameter of the cylindrical electrode 12 in which the direction orthogonal to the paper surface is the height direction. A lower end of the flow passage formation portion 20 is open from a lower end of the film forming unit 14. That is, the film forming unit 14 includes a slit-shaped discharge port 20a having the longitudinal direction in a direction orthogonal to the transport direction of the workpiece Z, that is, a width direction of the workpiece Z, at a lower center end of the workpiece Z in the transport direction.

Further, a plasma generation gas supply passage 24 is provided to penetrate from an upper end of the flow passage formation portion 20 to an upper surface of the film forming unit 14. A supply source of plasma generation gas (not shown) is connected to the plasma generation gas supply passage 24.

In the film forming apparatus 10, the cylindrical electrode 12 and the film forming unit 14 configure a pair of electrodes in the atmospheric plasma. Therefore, a space between the cylindrical electrode 12 and the film forming unit 14 (an inner wall surface of the flow passage formation portion 20) is an inner side flow passage for introducing the plasma generation gas.

Therefore, the plasma generation gas is made into plasma by the dielectric barrier discharge and is introduced between the pair of electrodes and the workpiece Z from the discharge port 20a on a lower surface of the film forming unit 14 while passing through the inner side flow passage between the cylindrical electrode 12 and the film forming unit 14 from the plasma generation gas supply passage 24. That is, the discharge port 20a is a discharge port for gas from the inner side flow passage.

The film forming unit 14 is provided with an upstream side raw material gas supply passage 26 and a downstream side raw material gas supply passage 28 to interpose the flow passage formation portion 20 in the lateral direction in the drawing. Both the upstream side raw material gas supply passage 26 and the downstream side raw material gas supply passage 28 are cylindrical-shaped spaces having the height direction in a direction orthogonal to the paper surface.

A supply source of the raw material gas (mixed gas of the raw material gas and the plasma generation gas) (not shown) is connected to both the upstream side raw material gas supply passage 26 and the downstream side raw material gas supply passage 28.

The film forming unit 14 is further provided with an upstream side flow passage 30 and a downstream side flow passage 32 to be positioned outside of the inner side flow passage with respect to the transport direction of the workpiece Z. Specifically, the upstream side flow passage 30 is positioned on the upstream side of the inner side flow passage, and the downstream side flow passage 32 is positioned on the downstream side of the inner side flow passage.

That is, the upstream side flow passage 30 is positioned on the upstream side of the inner side flow passage in the relative movement direction of the workpiece Z with respect to the pair of electrodes, and the downstream side flow passage 32 is positioned on the downstream side of the inner side flow passage in the relative movement direction of the workpiece Z with respect to the pair of electrodes.

The upstream side flow passage 30 communicates from the upstream side raw material gas supply passage 26 to the discharge port 30a on the lower surface of the film forming unit 14. The discharge port 30a is positioned on the upstream side of the discharge port 20a of the inner side flow passage. The discharge port 30a is a slit-shaped opening having the longitudinal direction in the width direction of the workpiece Z, that is, a direction orthogonal to the transport direction of the workpiece Z.

The downstream side flow passage 32 communicates from the downstream side raw material gas supply passage 28 to the discharge port 32a on the lower surface of the film forming unit 14. The discharge port 32a is positioned on the downstream side of the discharge port 20a of the inner side flow passage. The discharge port 32a is a slit-shaped opening having the longitudinal direction in the width direction of the workpiece Z.

The slit lengths of the discharge port 20a of the inner side flow passage, the discharge port 30a of the upstream side flow passage 30, and the discharge port 32a of the downstream side flow passage 32 may be appropriately set according to the width of the workpiece Z on which the film formation is assumed.

As described above, in the illustrated example, the film formation is performed on the workpiece Z while transporting the workpiece Z.

Here, in the remote diffusion mixing type atmospheric plasma film formation, normally, the gas flow passages (discharge ports) for introducing the raw material gas are provided to interpose the inner side flow passage (discharge port 20a) in the transport direction of the workpiece.

Therefore, in the film forming apparatus 10, in a preferred aspect, the discharge port 30a of the upstream side flow passage 30 and the discharge port 32a of the downstream side flow passage 32 are provided to interpose the discharge port 20a of the inner side flow passage in the transport direction of the workpiece Z. Further, as described above, in a preferred aspect, the discharge port 20a of the inner side flow passage, the discharge port 30a of the upstream side flow passage 30, and the discharge port 32a of the downstream side flow passage 32 have a slit shape having the longitudinal direction in a direction orthogonal to the transport direction of the workpiece Z.

The atmospheric plasma processing method and the atmospheric plasma processing apparatus according to the embodiment of the present invention are not limited to using the cylindrical electrode as in the film forming apparatus 10 shown in FIG. 1.

That is, the embodiment of the present invention can use various known atmospheric plasma film formations such as a configuration having an inner side flow passage between two flat plate electrodes and having an upstream side flow passage and a downstream side flow passage positioned upstream and downstream of the flat plate electrodes, for example, as shown in the above-mentioned JP2015-185494A, and a configuration shown in FIG. 6, as long as p*, which will be described later, satisfies 0<p*≤9.

Here, the flat plate electrode has corner portions. Therefore, in a case where the electrode and the workpiece are brought close to each other, an abnormal discharge may occur. In contrast, since the cylindrical electrode does not have a corner portion, it is extremely unlikely that an abnormal discharge occurs even in a case where the electrode and the workpiece are brought close to each other. In consideration of this point, in the embodiment of the present invention, it is preferable to use the cylindrical electrode 12 such as the film forming apparatus 10 in the illustrated example, rather than the flat plate electrode.

In the film forming apparatus 10, the AC power source 16 is connected to the cylindrical electrode 12. Further, the cylindrical electrode 12 and the film forming unit 14 configuring the pair of electrodes are grounded.

Therefore, by applying an AC voltage to the cylindrical electrode 12, a dielectric barrier discharge is generated between the cylindrical electrode 12 and the film forming unit 14 (the inner wall surface of the flow passage formation portion 20). As a result, the plasma generation gas, which flows between the cylindrical electrode 12 that is the inner side flow passage and the film forming unit 14, is excited, and plasma is generated.

The AC power source 16 is a known high-frequency AC power source used for the atmospheric plasma film formation.

In the embodiment of the present invention, a frequency (frequency of plasma excitation power) and an output (plasma excitation power) of the AC power source 16 are not limited, and the frequency and the output may be appropriately set according to the film that is used for the film formation, the raw material gas, the plasma generation gas, the desired film forming speed, or the like.

In the embodiment of the present invention, a pulse power source may be used instead of the AC power source.

In the film forming apparatus 10 shown in FIG. 1, at the time of the film formation on the workpiece Z, similar to the known remote diffusion mixing type atmospheric plasma film formation, the plasma generation gas is supplied between the cylindrical electrode 12 that is the inner side flow passage and the film forming unit 14 (the inner wall surface of the flow passage formation portion 20) while applying the AC voltage to the cylindrical electrode 12. As a result, the plasma generation gas, which passes through the inner side flow passage to generate the plasma, and the plasma generation gas, which includes the plasma, is introduced between the pair of electrodes and the workpiece Z from the discharge port 20a. In the film forming apparatus 10, the cylindrical electrode 12 and the film forming unit 14 configure the pair of electrodes as described above.+9

In parallel, the raw material gas (the mixed gas of the raw material gas and the plasma generation gas) is supplied to the upstream side flow passage 30 and to the downstream side flow passage 32, and the raw material gas is introduced between the pair of electrodes and the workpiece Z from the discharge port 30a and the discharge port 32a.

As a result, the plasma and the raw material gas are diffused and mixed between the pair of electrodes and the workpiece Z, the raw material gas is activated, and the film formation is performed on the workpiece Z by the active species of the generated raw material gas.

In the film forming apparatus 10 of the illustrated example, a flow rate of the plasma generation gas that is introduced from the inner side flow passage and a flow rate of the gas that is introduced from the upstream side flow passage 30 and the downstream side flow passage 32 are not limited, and the flow rates may be appropriately set according to the type of gas to be used, the desired film forming speed, the transportation speed of the workpiece Z, or the like. In the following description, the plasma generation gas is also simply referred to as plasma gas.

The mixed gas in which the raw material gas and the plasma gas are mixed is usually introduced from the upstream side flow passage 30 and the downstream side flow passage 32. The amount ratio of the raw material gas to the plasma gas in the mixed gas is also not limited, and the amount ratio may be appropriately set according to the type of gas to be used, the desired film forming speed, the transportation speed of the workpiece Z, or the like.

Here, in the film forming apparatus 10 (film forming method) of the embodiment of the present invention, in a case where a distance between the pair of electrodes and the workpiece Z is denoted by h, the transportation speed of the workpiece Z is denoted by U, a viscosity of gas existing between the pair of electrodes and the workpiece Z is denoted by μ, a gas pressure between the pair of electrodes and the workpiece Z is denoted by P, and a position in the transport direction of the workpiece Z is denoted by x, p*, which is represented by Expression “p*=(h²/2Uμ)×(−dP/dx)”, satisfies 0<p*≤9.

According to the embodiment of the present invention, by having such a configuration, it is possible to suppress a decrease in the film forming speed (processing speed) caused by the accompanying gas generated by the transport of the workpiece Z and to perform highly efficient film formation (the plasma processing) using the atmospheric plasma.

As described above, according to the studies of the present inventors, in a case where the film formation is performed using the atmospheric plasma while transporting the workpiece Z, the accompanying gas is generated, which is moved such that the atmosphere on the surface of the workpiece Z is pulled, due to the transport of the workpiece Z, and thereby a layer of the accompanying gas is formed on the surface of the workpiece Z on which the film formation is performed.

As a result, deactivation of the plasma and activated raw material gas, in which the activated raw material gas cannot come into contact with the workpiece Z, due to the accompanying gas, diffusion inhibition of the plasma and raw material gas, outflow of the plasma and raw material gas from a film forming region, and the like occur, and the generation time of the active species and the reaction time of the active species of the plasma and raw material gas are reduced, and thereby the film forming speed decreases.

Further, the decrease in the film forming speed increases as the transportation speed of the workpiece Z increases.

The film forming region is a region where the plasma gas (plasma) and the raw material gas (active species of the raw material gas), which are positioned between the pair of electrodes and the workpiece Z, are in contact with the workpiece Z.

FIG. 2 shows changes in the film forming speed in a case where the transportation speed of the workpiece Z is changed from 1-200 m/min (meters/min), in the atmospheric plasma film formation using the film forming apparatus shown in FIG. 1.

The example shown in FIG. 2 is an example in which the flow rate of the raw material gas from the downstream side flow passage 32 is fixed to 6.7 L/min (liters/min), and the DLC film is used for the film formation in the same manner as in examples described later, except that the transportation speed is changed. Further, in FIG. 2, the film forming speed is standardized based on the film forming speed in a case where the transportation speed is 1 m/min.

As shown in FIG. 2, the film forming speed decreases as the transportation speed of the workpiece Z increases due to the accompanying gas, and, for example, in a case where the transportation speed is 200 m/min, the film forming speed decreases substantially by 30% of that in a case where the transportation speed is 1 m/min.

In contrast, in the embodiment of the present invention, the gas flow between the pair of electrodes (the cylindrical electrode 12) and the workpiece Z is controlled such that p*, which is represented by “p*=(h/2Uμ)×(−dP/dx)”, satisfies 0<p*≤9.

Preferably, in at least a portion between the pair of electrodes and the workpiece Z, the gas flow between the cylindrical electrode 12 and the workpiece Z is controlled such that the gas flow is generated in a direction opposite to the transport direction of the workpiece Z, that is, from downstream toward upstream.

According to the embodiment of the present invention, by having such a configuration, it is possible to suppress a decrease in the film forming speed caused by the accompanying gas generated by the transport of the workpiece Z and to perform highly efficient film formation using the atmospheric plasma.

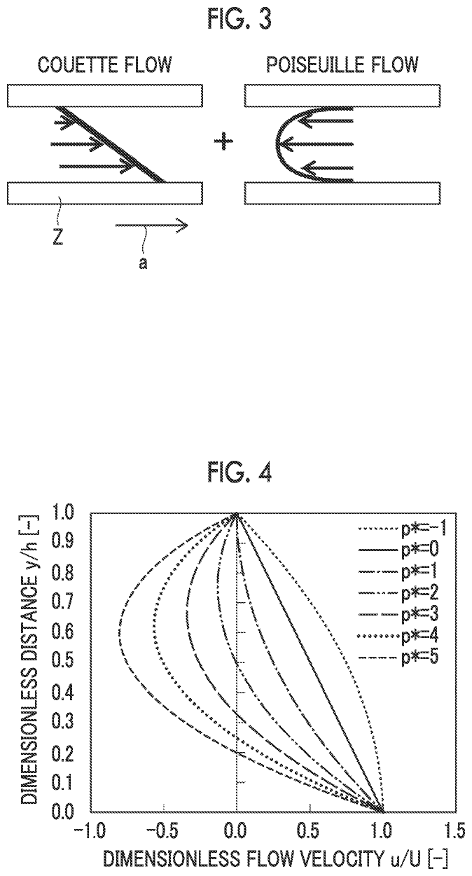

FIG. 3 conceptually shows the gas flow between the workpiece Z and the pair of electrodes in a case where the film formation is performed using the atmospheric plasma while transporting the workpiece Z.

In the atmospheric plasma film formation accompanied by the transport of the workpiece Z, the gas flow between the workpiece Z and the pair of electrodes can be approximated by the Couette-Poiseuille flow, which is the sum of a Couette flow, which is generated by the transport of the workpiece Z (in a direction of arrow a) shown on the left side in FIG. 3, and a Poiseuille flow with introduction of gas shown on the right side in FIG. 3. That is, the accompanying gas is gas generated by the Couette flow.

Here, in a case where

a distance from the workpiece Z in a spacing direction between the workpiece Z (processing target) and the pair of electrodes is denoted by y (hereinafter referred to as a spacing distance y),

a distance (interval, gap) between the pair of electrodes and the workpiece Z is denoted by h (hereinafter referred to as a gap distance h),

a gas flow velocity at the spacing distance y is denoted by u,

the transportation speed of the workpiece Z that is the relative movement speed between the workpiece Z and the pair of electrodes is denoted by U,

a viscosity of gas existing between the workpiece Z and the pair of electrodes is denoted by μ,

a gas pressure between the pair of electrodes and the workpiece Z is denoted by P, and

a position in the transport direction of the workpiece Z is denoted by x, a flow velocity distribution of the Couette-Poiseuille flow (steady state) between parallel flat plates is represented by the following expression.

u/U={1−y/h}−p*{y/h(1−y/h)}

p*=(h²/2Uμ)×(−dP/dx)

The viscosity μ of the gas existing between the workpiece Z (processing target) and the pair of electrodes is approximated by the viscosity of the typical composition of the mixed gas in a case where the plasma gas and the raw material gas exist between the workpiece and the electrodes. The typical composition of the mixed gas is specifically the composition of the mixed gas in accordance with the supply amount ratio of the plasma gas and the raw material gas supplied to the film forming unit, that is, the composition of the mixed gas supplied to the film forming unit.

Here, by using the relative movement speed U between the pair of electrodes and the workpiece Z and the gap distance h between the pair of electrodes and the workpiece Z, the spacing distance y from the workpiece Z in the spacing direction between the workpiece Z and the pair of electrodes, and the gas flow velocity u at the spacing distance y can be made dimensionless (standardized). Correspondingly, in the following description, a speed ratio u/U between the relative movement speed U of the workpiece Z with respect to the pair of electrodes, and the gas flow velocity u is referred to as a dimensionless flow velocity. Further, a relative distance y/h, which is the spacing distance y from the workpiece Z with respect to the gap distance h between the pair of electrodes and the workpiece Z, is referred to as a dimensionless distance.

Therefore, in the above-mentioned logical expression, the distribution of the gas flow between the pair of electrodes and the workpiece Z can be defined by p*.

Therefore, by controlling p*, it is possible to control the gas flow between the processing target and the pair of electrodes and to suppress a decrease in the film forming speed due to the accompanying gas.

FIG. 4 shows an example of the gas flow velocity distribution between the pair of electrodes and the workpiece Z with respect to p*. Here, a lateral axis represents the dimensionless flow velocity u/U, and a vertical axis represents the dimensionless distance y/h.

For example, the gas flow velocity distribution, which is indicated by p*=2.0 in FIG. 4, corresponds to the gas flow velocity distribution when substantially 2 L/min of gas is flown from the discharge port 32a of the downstream side flow passage 32, where the transportation speed of the workpiece Z is set to 200 m/min, the spacing distance between the pair of electrodes and the workpiece Z is set to 0.5 mm, and the gas supply width (slit width of the discharge port) in the width direction of the workpiece Z is set to 60 mm in the film forming apparatus 10 shown in FIG. 1.

Here, regarding the relative movement speed of the workpiece Z with respect to the pair of electrodes, a speed in the transport direction of the workpiece Z, that is, from upstream toward downstream, is set to positive, and a speed toward the opposite direction is set to negative.

Therefore, a position where the dimensionless distance y/h=1 and the dimensionless flow velocity u/U=0 is in a state in which there is no gas flow, and a region where the dimensionless flow velocity u/U<0.0 is a region in which the gas flow is generated in a direction opposite to the transport direction of the workpiece Z, that is, a region in which the gas flow is generated in a negative (minus) direction with respect to the transport direction of the workpiece Z.

As shown in FIG. 4, regardless of p*, the Couette flow dominates the gas flow on the surface of the workpiece Z, that is, in the position where the dimensionless distance y/h is 0.0 at the point in which the dimensionless flow velocity u/U is 1.0.

Further, in a region close to the workpiece Z, that is, in a region where the dimensionless distance y/h is small, the gas flow is greatly influenced by the transport of the workpiece Z, that is, the Couette flow. Therefore, regardless of p*, the gas flow in the region where the dimensionless distance y/h is small is in a plus direction from upstream toward downstream.

In a case where p* is “0”, the state is one in which there is no influence of the Poiseuille flow, and only the Couette flow dominates the gas flow. Therefore, the plasma processing efficiency is reduced due to the Couette flow, that is, the accompanying gas. For example, in the case of the film forming apparatus 10 shown in FIG. 1, it corresponds to a case where exactly the same amount (including 0) of the gas is introduced from the upstream side flow passage 30 and the downstream side flow passage 32.

In a case where p* is less than 0, the dimensionless flow velocity increases to a plus side. Therefore, the inflow of the Couette flow, that is, the accompanying gas flow, cannot be suppressed, and the plasma processing efficiency is further reduced. For example, in the case of the film forming apparatus 10 shown in FIG. 1, it corresponds to a case where the gas is introduced from the upstream side flow passage 30.

In contrast, in a case where p* exceeds 0, a region in which the dimensionless flow velocity approaches 0 is created, and in a case where p* exceeds 2, a region in which the dimensionless flow velocity u/U becomes negative is created.

As described above, the region in which the dimensionless flow velocity u/U becomes negative is a region in which the gas flow from downstream to upstream opposite to the transport direction of the workpiece Z is generated. That is, in the region, it is considered that the Poiseuille flow, which flows in a direction opposite to the transport direction of the workpiece Z, cancels the Couette flow.

On the other hand, as p* increases, the gas flow, which flows in a direction opposite to the transport direction of the substrate Z, becomes stronger. Here, in a case where p* exceeds 9, the gas flow, which flows in the direction opposite to the transport direction of the substrate Z, is too strong, and the residence time of the plasma and of the raw material gas in the film forming region is shortened, and conversely, the film forming speed decreases.

Therefore, according to the embodiment of the present invention of controlling the gas flow between the pair of electrodes and the substrate Z such that p*, which is represented by “p*=(h²/2Uμ)×(−dP/dx)”, satisfies 0<p*≤9 in a case where the film formation is performed using the atmospheric plasma while transporting the substrate Z, it is possible to suppress the inflow of the accompanying gas generated by the transport of the substrate Z into the film forming region, it is possible to suppress contact inhibition between the raw material gas and the substrate Z due to the accompanying gas, deactivation of the plasma and activated raw material gas, and diffusion inhibition of the plasma and the raw material gas, and then it is possible to sufficiently ensure the generation time of the active species and the reaction time of the active species of the plasma and the raw material gas.

As a result, according to the embodiment of the present invention, it is possible to suppress a decrease in the film forming speed due to the accompanying gas that accompanies the transport of the substrate Z and to perform highly efficient film formation using the atmospheric plasma.

Here, in the embodiment of the present invention, in order to suppress the inflow of the accompanying gas into the film forming region and to suitably suppress the adverse influence by the accompanying gas, it is more preferable that there is a region where the dimensionless flow velocity u/U is negative for the gas flow velocity distribution between the pair of electrodes and the substrate Z. That is, in the embodiment of the present invention, it is more preferable that there is a region between the pair of electrodes and the substrate Z in which the gas flow is in a direction from downstream to upstream, which is opposite to the transport direction of the substrate Z. In consideration of this point, p* is more preferably 2 or more.

In consideration of the above point, it is preferable that p* satisfies 2≤p*≤6.

The calculation method of p* is not limited, and various methods can be used. The following Method 1 and Method 2 are exemplified as preferable calculation methods.

<Method 1>

I. “A gap distance h between the pair of electrodes and the workpiece”, “a width w of the gas supply flow passage from the inner side flow passage in the direction orthogonal to the transport direction of the workpiece”, “a flow rate Q of the gas supplied from the inner flow passage flowing in the opposite direction to the transport direction of the workpiece in the flow passage cross section defined by the gap distance h and the width w”, and “a transportation speed U of the workpiece” are measured. Here, in a case where it is difficult to measure the gap distance h and the width w, a flow passage cross-sectional area A defined by the gap distance h and the width w may be measured. Further, in a case where the gas is introduced from both the upstream side flow passage and the downstream side flow passage, a value obtained by subtracting “a gas flow rate introduced from the upstream side flow passage” from “a gas flow rate introduced from the downstream side flow passage” is used as the gas flow rate Q.

“An average flow velocity vₐᵥₑ of the gas supplied from the inner flow passage flowing in a direction opposite to the transport direction of the workpiece Z in the flow passage cross section defined by the gap distance h and the width w”, which is appropriately measured by using the relational expression described later instead of the gas flow rate Q, may be used.

The average flow velocity vₐᵥₑ may be measured, for example, by flowing the gas from the inner side flow passage in a state in which the pair of electrodes and the workpiece are relatively stationary and by using a wind speed meter, an air flow visualization device, or the like.

The flow rate Q and the flow velocity v are the flow rate and the flow velocity of only the planar Poiseuille flow component.

II. p* is obtained from the relational expression “p*=6Q/(hwU)=6Q/(AU)”.

Here, in the above relational expression, since “the gas flow that is introduced from the downstream side toward the upstream side in the flow passage cross section” is considered to ideally form the Poiseuille flow, the gas flow rate is obtained by using the fact that the gas flow rate in the planar Poiseuille flow is theoretically represented by Q=w×h³×(−dP/dx)/(12μ) and the fact that p*=(h²/2Uμ)×(−dP/dx).

In a case where vₐᵥₑ is used, since vₐᵥₑ=Q/A, p* can be obtained from p*=6 vₐᵥₑ/U.

<Method 2>

I. The flow velocity of the gas at each position in the spacing direction between the pair of electrodes (the cylindrical electrodes 12) and the workpiece Z is measured using an air flow visualization apparatus or the like.

II. The relationship between the dimensionless distance y/h and the dimensionless flow velocity u/U is plotted based on values of the transportation speed U of the workpiece Z and the gap distance h between the pair of electrodes and the workpiece Z.

III. p* is obtained by fitting based on the flow velocity distribution.

Further, in Method 1 and Method 2, “the transport direction of the workpiece” means, that is, “the relative movement direction between the workpiece and the pair of electrodes”, “from the downstream side to the upstream side of the transport direction of the workpiece” means, that is, “from the downstream side to the upstream side in the relative movement direction of the workpiece with respect to the pair of electrodes”, and “the transportation speed U of the workpiece” means, that is, “the relative movement speed U between the pair of electrodes and the workpiece”. Regarding the above points, the same applies to the following description.

As the calculation method for p*, “p*=6vₐᵥₑ/U” can also be used as described above.

In the same manner as the previous description,

the spacing distance from the workpiece Z in the spacing direction between the workpiece and the pair of electrodes is denoted by y,

the gap distance between the pair of electrodes and the workpiece Z is denoted by h,

the gas flow velocity at the spacing distance y is denoted by u,

the transportation speed of the workpiece, that is, the relative movement speed between the workpiece Z and the pair of electrodes, is denoted by U,

a viscosity of gas existing between the workpiece and the pair of electrodes is denoted by μ,

a gas pressure between the pair of electrodes and the workpiece Z is denoted by P,

a position in the transport direction of the workpiece Z is denoted by x,

the width of the gas supply flow passage from the inner side flow passage in a direction orthogonal to the transport direction of the workpiece is denoted by w,

the flow rate of the gas supplied from the inner flow passage flowing in a direction opposite to the transport direction of the workpiece in the flow passage cross section defined by the gap distance h and the width w is denoted by Q,

the average flow velocity of the gas supplied from the inner side flow passage flowing in a direction opposite to the transport direction of the workpiece Z in the flow passage cross section defined by the gap distance h and the width w is denoted by vₐᵥₑ, and

the flow passage cross-sectional area defined by the gap distance h and the width w is denoted by A.

As described above, the flow rate Q and the flow velocity v are the flow rate and the flow velocity of only the planar Poiseuille flow component.

As described above, the flow velocity distribution of the Couette-Poiseuille flow (the steady state) between the parallel flat plates is represented by the following expressions.

u/U={1−y/h}−p*{y/h(1−y/h)} Expression 1

p*=(h²/2Uμ)×(−dP/dx) Expression 2

On the other hand, the flow velocity distribution of the Poiseuille flow (the steady state) between the parallel flat plates is represented by the following expression.

u=(h2/2μ)×(−dP/dx){y/h(1−y/h)}

Here, the gas flow rate Q in the Poiseuille flow is considered as follows.

$$\text{?}$$

$$\text{?} \text{indicates text missing or illegible when filed}$$

Therefore, from Expression 2 described above, p* can be represented as follows.

Q=(hwU/6)(h2/2Uμ)×(−dP/dx)=(hwU/6)p*

p*=6Q/hwU=6(Q/AU)=6(vₐᵥₑ/U)

The following relationships may be used for A and vₐᵥₑ.

A=hw

vₐᵥₑ=Q/A

That is, p* is considered to be a value six times the dimensionless average flow velocity of the gas (which forms the Poiseuille flow) supplied from the inner flow passage flowing from the downstream side toward the upstream side in the flow passage cross section defined by the gap distance h and the width w described above.

From the above point, the above-described Expression 1 can also be represented as follows.

u/U={1−y/h}−6(y/h)(1−y/h)(vₐᵥₑ/U)

In the embodiment of the present invention, the transportation speed of the workpiece Z is not limited and may be appropriately set according to the required productivity, the type of the film that is used for the film formation, the type of the gas to be used, or the like.

Here, as shown in FIG. 2, in the atmospheric plasma film formation accompanied by the transport of the workpiece Z, the decrease in the film forming speed increases as the transportation speed of the workpiece Z increases. In other words, the effect of the embodiment of the present invention is more suitably obtained as the transportation speed of the workpiece Z becomes faster.

On the other hand, as the relative speed U of the workpiece Z with respect to the pair of electrodes increases, the flow of the gas between the pair of electrodes and the workpiece Z becomes turbulent, and it becomes difficult to handle the gas flow as the “Couette-Poiseuille flow (the steady state)” described above. That is, a discussion in terms of p* becomes difficult.

Further, the turbulence of the gas also changes depending on the gap distance h between the pair of electrodes and the substrate Z, the width w of the gas supply flow passage from the inner side flow passage in the direction orthogonal to the transport direction (the relative movement direction) of the workpiece Z, and the viscosity μ and density p of the gas existing between the pair of electrodes and the substrate Z, which may also be difficult to discuss in terms of p*.

In consideration of this point, in a case where a hydraulic diameter D=2hw/(h+w) is used, in the embodiment of the present invention, there is a suitable range of Reynolds number Re=ρUD/μ, and substantially 0<Re<3000 is preferable, and 0<Re<2000 is more preferable.

In the embodiment of the present invention, the method of controlling the gas flow between the pair of electrodes, that is, the cylindrical electrodes 12 and the workpiece Z, in such a manner that 0<p*≤9 is satisfied is not limited, and various flow control methods can be used.

As an example, a method of making the flow rate (the downstream side gas flow rate) of the gas, which is introduced from the downstream side flow passage 32 (the discharge port 32a), larger than the flow rate (the upstream side gas flow rate) of the gas, which is introduced from the upstream side flow passage 30 (the discharge port 30a), is exemplified.

According to this method, since the gas flows from downstream toward upstream, it is possible to suppress the inflow of the accompanying gas into the film forming region, and as a result, 0<p*≤9 can be satisfied, and thereby, preferably, a flow of the gas, which flows from downstream to upstream is generated between the pair of electrodes and the workpiece Z to suppress a decrease in the film forming speed caused by the accompanying gas, and highly efficient atmospheric plasma film formation can be performed.

As another method, a method of making a first gas flow rate and a second gas flow rate unequal is exemplified by equalizing the introduction amounts of the gas from the upstream side flow passage 30 and the downstream side flow passage 32 and making the discharge port 30a of the upstream side flow passage 30 and the discharge port 32a of the downstream side flow passage 32 different in area. In the illustrated example, a method of making the first gas flow rate and the second gas flow rate unequal is exemplified by setting the widths of the slits to different widths.

For example, the introduction amounts of the gas are made equal, and the width of the slit of the discharge port 32a is made smaller than that of the discharge port 30a. As a result, the flow velocity of the gas introduced from the discharge port 32a is faster than the flow velocity of the gas introduced from the discharge port 30a.

According to this method, in the same manner as the previous description, since the gas flows from downstream toward upstream, it is possible to suppress the inflow of the accompanying gas into the film forming region, and as a result, 0<p*≤9 can be satisfied, and thereby, preferably, a flow of the gas, which flows from downstream to upstream is generated between the pair of electrodes and the workpiece Z to suppress a decrease in the film forming speed caused by the accompanying gas, and highly efficient atmospheric plasma film formation can be performed.

As another method, for example, a method in which an air supply unit that supplies the gas to the downstream side of the inner side flow passage is provided and air is supplied from the air supply unit, for example, film-shaped gas (curtain gas), is exemplified.

For example, in the film forming unit 14, a gas film formation unit is provided on the side opposite to the inner side flow passage of the downstream side flow passage 32, that is, downstream of the downstream side flow passage 32, and the curtain gas is supplied toward the workpiece Z. The flow of the gas from the downstream side flow passage 32 toward downstream (the right side) is cut off by the curtain gas.

According to this method, in the same manner as the previous description, since the gas flows from downstream toward upstream, it is possible to suppress the inflow of the accompanying gas into the film forming region, and as a result, 0<p*≤9 can be satisfied, and thereby, preferably, a flow of the gas, which flows from downstream to upstream is generated between the pair of electrodes and the workpiece Z to suppress a decrease in the film forming speed caused by the accompanying gas, and highly efficient atmospheric plasma film formation can be performed.

As another method, a method of providing an exhaust unit on the upstream side of the inner side flow passage and exhausting the gas from the exhaust unit is exemplified.

For example, in the film forming unit 14, the exhaust unit is provided on the side opposite to the inner side flow passage of the upstream side flow passage 30, that is, upstream of the upstream side flow passage 30, and the gas is discharged from the exhaust unit.

According to this method, in the same manner as the previous description, since the gas flows from downstream toward upstream, it is possible to suppress the inflow of the accompanying gas into the film forming region, and as a result, 0<p*≤9 can be satisfied, and thereby, preferably, a flow of the gas, which flows from downstream to upstream is generated between the pair of electrodes and the workpiece Z to suppress a decrease in the film forming speed caused by the accompanying gas, and highly efficient atmospheric plasma film formation can be performed.

As yet another method, a method in which shapes of regions of the electrodes facing the workpiece Z are made different between the upstream side flow passage 30 side and the downstream side flow passage 32 side is exemplified.

For example, in the film forming unit 14, the shapes of the electrode surfaces in the regions facing the workpiece Z are adjusted such that a distance between the film forming unit 14 on the downstream side flow passage 32 side and the workpiece Z is narrower than a distance between the film forming unit 14 on the upstream side flow passage 30 side and the workpiece Z.

According to this method, in the same manner as the previous description, since the gas flows from downstream toward upstream, it is possible to suppress the inflow of the accompanying gas into the film forming region, and as a result, 0<p*≤9 can be satisfied, and thereby, preferably, a flow of the gas, which flows from downstream to upstream is generated between the pair of electrodes and the workpiece Z to suppress a decrease in the film forming speed caused by the accompanying gas, and highly efficient atmospheric plasma film formation can be performed.

In the embodiment of the present invention, two or more of these methods may be used in combination to satisfy 0<p*≤9 and preferably to generate the gas flow from downstream toward upstream between the pair of electrodes and the workpiece Z.

Further, these methods can also be used in the configurations shown in JP2015-185494A and FIG. 6.

The above description is an example in which the embodiment of the present invention is used for the film formation using the atmospheric plasma, but as described above, the embodiment of the present invention is also suitably used for processing workpieces in the atmospheric plasma.

That is, in the embodiment of the present invention, by replacing the film formation (the plasma film formation) with the processing (the plasma processing) in the above description, essentially, the same actions and effects can be obtained, such as improvement of the processing efficiency.

Although the atmospheric plasma processing method and the atmospheric plasma processing apparatus of the embodiment of the present invention have been described in detail above, the embodiment of the present invention is not limited to the above examples, and various improvements and modifications may be made without departing from the scope of the embodiment of the present invention.

### Examples

Hereinafter, the embodiment of the present invention will be described in more detail with reference to specific examples of the present invention.

However, the embodiment of the present invention is not limited to the following examples.

### Examples

A DLC film was used for the film formation on the workpiece Z using the film forming apparatus 10 shown in FIG. 1.

As the workpiece Z, a long PEN film having a width of 60 mm and a thickness of 4 μm was used.

A distance between the lowermost portion of the cylindrical electrode 12 and the lower surface of the film forming unit 14, and the workpiece Z was set to 2 mm.

The cylindrical electrode 12 was used in which the surface of a stainless steel cylinder having a diameter of 17 mm and a length of 60 mm was covered with quartz glass having a thickness of 1.5 mm.

The film forming unit 14 was made of stainless steel. The cylindrical-shaped flow passage formation portion 20 was provided at the center of the film forming unit 14 in the lateral direction such that the lower part was open. Further, the plasma generation gas supply passage 24 was formed to communicate with the flow passage formation portion 20.

The cylindrical electrode 12 was inserted into the flow passage formation portion 20 such that the centers of the cylinders coincided with each other. A distance between the cylindrical electrode 12 and the film forming unit 14 (the inner wall surface of the flow passage formation portion 20) was set to 1.5 mm. The inner side flow passage was formed between the cylindrical electrode 12 and the film forming unit 14 as described above. Therefore, the width (the slit width) of the inner side flow passage was 1.5 mm.

Further, the film forming unit 14 was formed with the upstream side raw material gas supply passage 26 and the upstream side flow passage 30, and with the downstream side raw material gas supply passage 28 and the downstream side flow passage 32. The slit widths of the discharge port 30a of the upstream side flow passage 30 and the discharge port 32a of the downstream side flow passage 32 were set to 0.5 mm. Further, in the upstream side flow passage 30 and the downstream side flow passage 32, the regions toward the discharge ports were set to an angle of 18° (162° with respect to the horizontal direction.

The slit lengths of the discharge port 20a of the inner side flow passage, the discharge port 30a of the upstream side flow passage 30, and the discharge port 32a of the downstream side flow passage 32 were all set to 60 mm.

The AC power source 16 having a frequency of 27.12 MHz was connected to the cylindrical electrode 12.

Further, the film forming unit 14 was grounded.

The film formation was performed on the workpiece Z using such a film forming apparatus 10.

Mixed gas of 99.1 vol % of argon gas, 0.7 vol % of nitrogen gas, and 0.2 vol % of oxygen gas was supplied to the inner side flow passage. The introduction amount of the mixed gas from the inner side flow passage was set to 2.3 L/min.

On the other hand, mixed gas of 99 vol % of argon gas and 1 vol % of propane gas was supplied to the upstream side flow passage 30 and to the downstream side flow passage 32.

The output of the AC power source 16 was set to 500 W.

The film forming atmosphere was set to normal temperature and normal pressure.

The transportation speed of the workpiece was set to 200 m/min.

Under the above conditions, the film formation using the DLC film was performed on the workpiece Z by fixing the introduction amount of the gas from the upstream side flow passage 30 to 6.7 L/min and changing the introduction amount of the gas from the downstream side flow passage 32 to

6.7 L/min,

10.9 L/min,

16.2 L/min,

22.7 L/min,

30.7 L/min,

42.7 L/min,

46.7 L/min, and

58.1 L/min, respectively.

p* was calculated by using Method 1 described above for each introduction amount of the gas from the downstream side flow passage 32.

As a result,

p* was 0 in a case where the introduction amount of the gas from the downstream side flow passage 32 was 6.7 L/min,

p* was 1.1 in a case where the introduction amount of the gas from the downstream side flow passage 32 was 10.9 L/min,

p* was 2.4 in a case where the introduction amount of the gas from the downstream side flow passage 32 was 16.2 L/min,

p* was 4 in a case where the introduction amount of the gas from the downstream side flow passage 32 was 22.7 L/min,

p* was 6 in a case where the introduction amount of the gas from the downstream side flow passage 32 was 30.7 L/min,

p* was 9 in a case where the introduction amount of the gas from the downstream side flow passage 32 was 42.7 L/min,

p* was 10 in a case where the introduction amount of the gas from the downstream side flow passage 32 was 46.7 L/min, and

p* was 13 in a case where the introduction amount of the gas from the downstream side flow passage 32 was 58.1 L/min.

Further, the film formation of DLC in which the film formation is performed under each condition was measured by using an ATR method (a total reflection measurement method). The film forming speed was calculated for each introduction amount of the gas from the downstream side flow passage 32 by using the film thickness of the DLC.

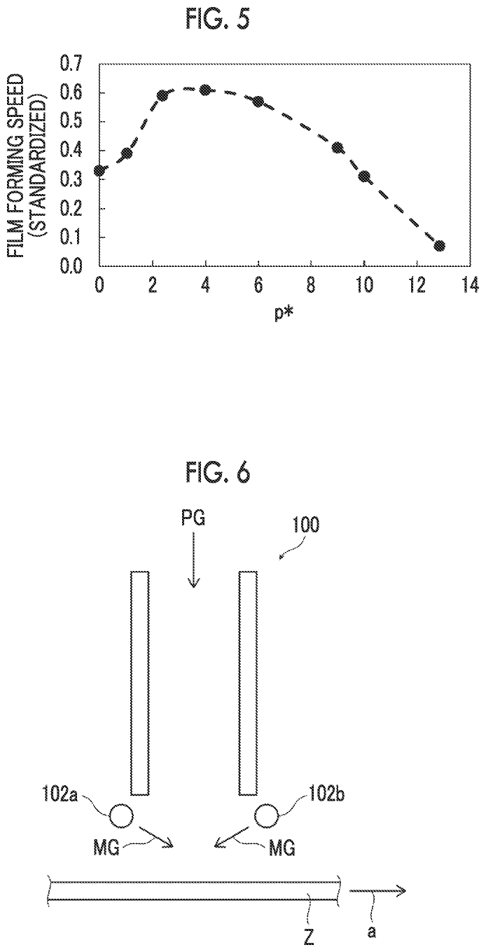

The relationship between the film forming speed and p* is shown in FIG. 5. The film forming speed is standardized based on the film forming speed at the transportation speed of 1 m/min in FIG. 2 described above.

As described above, the example shown in FIG. 2 is an example in which the introduction amount of the gas from the downstream side flow passage is fixed to 6.7 L/min, and the DLC film is used for the film formation in the same manner as in the present example, except that the transportation speed is changed. Therefore, in the present example, the case where the introduction amount of the gas from the downstream side flow passage 32 is 6.7 L/min (p*=0) and the case where the transportation speed of the workpiece Z in FIG. 2 is 200 m/min are the same film formation conditions and results.

As shown in FIGS. 2 and 5, in a case where p* is 0, that is, in a case where the introduction amounts of the gas from the upstream side flow passage and the downstream side flow passage are the same at 6.7 L/min, the film forming speed drops substantially by 30% as compared with the case where the transportation speed of the workpiece Z is 1 m/min, in a case where the transportation speed of the workpiece Z is 200 m/min.

In contrast, by setting p* exceeds 0, the film forming speed can be improved. In particular, by setting p* to 2-6, the film forming speed can be improved substantially by 60% with respect to a case where the transportation speed of the workpiece Z is 1 m/min.

On the other hand, in a case where p* exceeds 9, conversely, the film forming speed is slower than in a case where p* is 0. This is because, as described above, in a case where p* exceeds 9, the gas flow from the downstream side to the upstream side increases, and as a result, it is considered that the residence time of the plasma and of the activated raw material gas in the film forming region is shortened, and the film formation efficiency is lowered.

From the above results, the effect of examples of the present invention is clear.

The embodiment of the present invention can be suitably used for workpiece processing, film formation, and the like in the manufacture of various products.

### EXPLANATION OF REFERENCES

10: (atmospheric plasma) film forming apparatus
12: cylindrical electrode
14: film forming unit
16: AC power source
20: flow passage formation portion
20a, 30a, 32a: discharge port
24: plasma generation gas supply passage
26: upstream side raw material gas supply passage
28: downstream side raw material gas supply passage
30: upstream side flow passage
32: downstream side flow passage
100: pair of electrodes
102a, 102b: outer side flow passage
PG: plasma generation gas
MG: raw material gas
Z: workpiece

What is claimed is:

1. An atmospheric plasma processing method,
wherein in a case where processing of a workpiece is performed using atmospheric plasma by introducing plasma generation gas between a pair of electrodes and the workpiece from an inner side flow passage, which passes between the pair of electrodes, while relatively moving the pair of electrodes and the workpiece, and a distance between the pair of electrodes and the workpiece is denoted by h, a relative movement speed between the workpiece and the pair of electrodes is denoted by U, a viscosity of gas existing between the pair of electrodes and the workpiece is denoted by μ, a gas pressure between the pair of electrodes and the workpiece is denoted by P, and a position in a relative movement direction of the workpiece with respect to the pair of electrodes is denoted by x, p*, which is represented by Expression “p*=(h²/2Uμ)×(−dP/dx)”, satisfies 0<p*≤9.

2. The atmospheric plasma processing method according to claim 1,
wherein at least a portion between the pair of electrodes and the workpiece has a region in which gas flows in a direction opposite to the relative movement direction of the workpiece with respect to the pair of electrodes.

3. The atmospheric plasma processing method according to claim 1,
wherein plasma generation gas is further introduced from at least one of an upstream side flow passage positioned on an upstream side of the inner side flow passage in the relative movement direction of the workpiece with respect to the pair of electrodes or a downstream side flow passage positioned on a downstream side of the inner side flow passage in the relative movement direction of the workpiece with respect to the pair of electrodes.

4. The atmospheric plasma processing method according to claim 3,
wherein raw material gas used for performing film formation on the workpiece is introduced from at least one of the upstream side flow passage or the downstream side flow passage.

5. The atmospheric plasma processing method according to claim 3,
wherein the p* is set to satisfy 0<p*≤9 by making an introduction amount of gas from the downstream side flow passage larger than an introduction amount of gas from the upstream side flow passage.

6. The atmospheric plasma processing method according to claim 3,
wherein the p* is set to satisfy 0<p*≤9 by making a gas discharge port of the upstream side flow passage and a gas discharge port of the downstream side flow passage different in area.

7. The atmospheric plasma processing method according to claim 3,
wherein the p* is set to satisfy 0<p*≤9 by making shapes of surfaces of electrodes forming the pair of electrodes and facing the workpiece different between an upstream side flow passage side and a downstream side flow passage side.

8. The atmospheric plasma processing method according to claim 1,
wherein the p* is set to satisfy 0<p*≤9 by providing an air supply unit on a downstream side of the inner side flow passage in the relative movement direction of the workpiece with respect to the pair of electrodes and supplying air from the air supply unit.

9. The atmospheric plasma processing method according to claim 1,
wherein the p* is set to satisfy 0<p*≤9 by providing an exhaust unit on an upstream side of the inner side flow passage in the relative movement direction of the workpiece with respect to the pair of electrodes and exhausting air from the exhaust unit.

10. An atmospheric plasma processing apparatus, comprising:
a pair of electrodes;
a movement unit that relatively moves a workpiece and the pair of electrodes along a path facing the pair of electrodes;
an inner side flow passage that introduces gas between the pair of electrodes and the workpiece through between the pair of electrodes; and
a gas flow control unit that controls a gas flow between the pair of electrodes and the workpiece such that in a case where a distance between the pair of electrodes and the workpiece is denoted by h, a relative movement speed between the pair of electrodes and the workpiece is denoted by U, a viscosity of gas existing between the pair of electrodes and the workpiece is denoted by μ, a gas pressure between the pair of electrodes and the workpiece is denoted by P, and a position in a relative movement direction of the workpiece with respect to the pair of electrodes is denoted by x, p*, which is represented by “p*=(h²/2Uμ)×(−dP/dx)”, satisfies 0<p*≤9.

11. The atmospheric plasma processing apparatus according to claim 10, further comprising:
an upstream side flow passage for introducing gas between the pair of electrodes and the workpiece, on an upstream side of the inner side flow passage in the relative movement direction of the workpiece with respect to the pair of electrodes; and
a downstream side flow passage for introducing gas between the pair of electrodes and the workpiece, on a downstream side of the inner side flow passage in the relative movement direction of the workpiece with respect to the pair of electrodes.
